(19) United States
(12) Patent Application Publication
(10) Pub. No.: US 2026/0276678 A1
(43) Pub. Date: Sep. 17, 2026

(54) VOLTAGE DETECTOR

(71) Applicant: eMemory Technology Inc., Hsin-Chu (TW)

(72) Inventors: Yin-Chia YANG, Hsinchu County (TW); Dung Le Tan Hoang, Hsinchu County (TW)

(21) Appl. No.: 19/564,260

(22) Filed: Mar. 12, 2026

Related U.S. Application Data
(60) Provisional application No. 63/771,080, filed on Mar. 13, 2025.

(51) Int. Cl. G01R 15/04; G01R 19/00

(52) U.S. Cl. CPC G01R 15/04; G01R 19/0038

(57) ABSTRACT

A voltage detector includes a comparator, a voltage divider, a reference voltage generating circuit and a start-up circuit. The output terminal of the comparator generates a detection signal. The voltage divider receives an input voltage and generates a divided voltage and a control signal. The divided voltage is transmitted to the first input terminal of the comparator. The reference voltage generating circuit receives the input voltage and a start signal and generates a reference voltage and a stop signal. The reference voltage is transmitted to the second input terminal of the comparator. The start-up circuit receives the input voltage, the control signal and the stop signal. When the start-up circuit is enabled, the start signal is activated. Consequently, the reference voltage is generated. After receiving the start signal, the reference voltage generating circuit generates the stop signal, and the start-up circuit stops activating the start signal.

This application claims the benefit of U.S. provisional application Ser. No. 63/771,080, filed Mar. 13, 2025, the subject matters of which is incorporated herein by reference.

### FIELD OF THE INVENTION

The present invention relates to a detector, and more particularly to a voltage detector.

### BACKGROUND OF THE INVENTION

Generally, a circuit module in an IC chip receives a corresponding operating voltage. If the operating voltage exceeds a certain threshold value, the circuit module is possibly damaged. Consequently, the IC chip needs to be equipped with a voltage detector to detect this operating voltage.

For example, in the memory module of the IC chip, word lines receive word line voltages, and bit lines receive bit line voltages. When the voltage received by the word line or the bit line is too high, the memory cells in the memory module may be damaged. Consequently, the IC chip needs to be equipped with a voltage detector to receive the word line voltage or bit line voltage. When the word line voltage or the bit line voltage is too high, the voltage detector generates a signal to notify the controller in the IC chip, and the controller takes protective actions on the memory module to prevent damage.

FIG. 1 is a schematic circuit diagram illustrating the circuitry structure of a conventional voltage detector. The voltage detector 100 can detect the input voltage V_{IN}. For example, the input voltage V_{IN} is a word line voltage or a bit line voltage.

The voltage detector 100 includes a current source 110, a comparator 120, and resistors R₁~R₃. The first terminal of the resistor R₁ receives the input voltage V_{IN}. The second terminal of the resistor R₁ is connected to the node a2. The first terminal of the resistor R₂ is connected to the node a2. The second terminal of the resistor R₂ receives a ground voltage (0 V). The current source 110 is connected between the input voltage V_{IN} and the node a1. The current source 110 generates a constant current I. The first terminal of the resistor R₃ is connected to the node a1. The second terminal of the resistor R₃ receives the ground voltage (0 V). Furthermore, the non-inverting input terminal of the comparator 120 is connected to the node a1, the inverting input terminal of the comparator 120 is connected to the node a2, and the output terminal of the comparator 120 generates a detection signal O_{DET}.

As can be understood from FIG. 1, the voltage V_{A2} at the node a2 can be expressed as: V_{A2}=(R₂×V_{IN})/(R₁+R₂), and the voltage at the node a1 can be expressed as: V_{A1}=I×R₃. When the voltage V_{A1} is higher than the voltage V_{A2}, the detection signal O_{DET} generated by the comparator 120 is in a logic high level state. When the voltage V_{A1} is lower than the voltage V_{A2}, the detection signal O_{DET} generated by the comparator 120 is in a logic low level state.

That is, when the input voltage V_{IN} is lower than [(I×R₃)×(R₁+R₂)/R₂], the detection signal O_{DET} is in the logic high level state. In addition, when the input voltage V_{IN} is higher than [(I×R₃)×(R₁+R₂)/R₂], the detection signal O_{DET} is in the logic low level state. Consequently, by appropriately designing the constant current I of the current source 110 and the resistance values of the resistors R₁~R₃, the voltage detector 100 can be used to determine the input voltage V_{IN}.

Generally, the voltage detector 100 is affected by process, voltage and temperature variations (also referred to as PVT variations).

### SUMMARY OF THE INVENTION

An embodiment of the present invention provides a voltage detector. The voltage detector receives an input voltage. The voltage detector includes a comparator, a voltage divider, a reference voltage generating circuit and a start-up circuit. The comparator has a first input terminal and a second input terminal. An output terminal of the comparator generates a detection signal. The voltage divider receives the input voltage and generates a divided voltage and a control signal. The divided voltage is transmitted to the first input terminal of the comparator. The divided voltage is equal to a proportional value multiplied by the input voltage. The proportional value is a real number greater than zero and less than or equal to 1. The reference voltage generating circuit receives the input voltage and a start signal and generates a reference voltage and a stop signal. The reference voltage is transmitted to the second input terminal of the comparator. The start-up circuit receives the input voltage, the control signal and the stop signal. The start-up circuit operates according to the control signal. When the start-up circuit is enabled, the start signal is activated by the start-up circuit. Consequently, the reference voltage generating circuit generates the reference voltage. After receiving the start signal, the reference voltage generating circuit generates the stop signal, and the start-up circuit stops activating the start signal.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) is a schematic circuit diagram illustrating the circuitry structure of a conventional voltage detector;

FIG. 2 is a schematic circuit block diagram illustrating the architecture of a voltage detector according to a first embodiment of the present invention;

FIG. 3A is a schematic circuit diagram illustrating the detailed circuitry structure of the voltage detector of the present invention;

FIG. 3B is a schematic timing waveform diagram illustrating associated signals processed by the voltage detector of the present invention;

FIG. 3C is a schematic circuit diagram illustrating a variant example of the bias current generating circuit;

FIG. 3D is a schematic circuit diagram illustrating a variant example of the PTAT voltage generating circuit;

FIG. 3E is a schematic circuit diagram illustrating a variant example of the CTAT voltage generating circuit;

FIG. 3F is a schematic circuit diagram illustrating another variant example of the CTAT voltage generating circuit;

FIG. 3G is a schematic circuit diagram illustrating a variant example of the voltage divider and the start-up circuit;

FIG. 4A is a schematic circuit block diagram illustrating the architecture of a voltage detector according to a second embodiment of the present invention;

FIG. 4B is a schematic circuit diagram illustrating a variant example of the reference voltage generating circuit in the voltage detector according to the second embodiment of the present invention; and

FIG. 4C is a schematic circuit diagram illustrating another variant example of the reference voltage generating circuit in the voltage detector according to the second embodiment of the present invention.

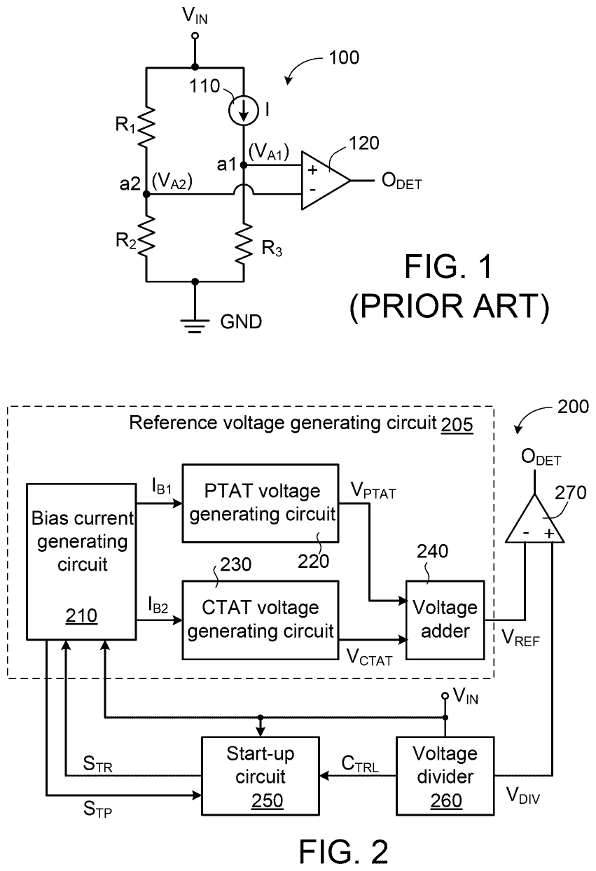

### DETAILED DESCRIPTION OF PREFERRED EMBODIMENTS

The present invention provides a voltage detector. When the voltage detector receives an input voltage, the voltage detector will be automatically activated to detect the magnitude of the input voltage.

FIG. 2 is a schematic circuit block diagram illustrating the architecture of a voltage detector according to a first embodiment of the present invention. As shown in FIG. 2, the voltage detector 200 includes a reference voltage generating circuit 205, a comparator 270, a voltage divider 260, and a start-up circuit 250. The voltage divider 260, the start-up circuit 250 and the reference voltage generating circuit 205 receive the input voltage V_{IN}.

The voltage divider 260 receives the input voltage V_{IN} and generates a divided voltage V_{DIV} and a control signal CTRL. The divided voltage V_{DIV} is transmitted to a first input terminal of the comparator 270.

The reference voltage generating circuit 205 receives the input voltage V_{IN} and a start signal S_{TR} and generates a reference voltage V_{REF} and a stop signal S_{TP}. The reference voltage V_{REF} is transmitted to a second input terminal of the comparator 270. The output terminal of the comparator 270 generates a detection signal O_{DET}. The first input terminal and the second input terminal of the comparator 270 are respectively the non-inverting input terminal and the inverting input terminal of the comparator 270. Alternatively, the first input terminal and the second input terminal of the comparator 270 are respectively an inverting input terminal and a non-inverting input terminal of the comparator 270.

The start-up circuit 250 receives the input voltage V_{IN}, the control signal CTRL and the stop signal S_{TP}. The operations of the start-up circuit 250 are controlled according to the control signal CTRL. When the start-up circuit 250 is enabled, the start signal S_{TR} is activated, and thus the reference voltage generating circuit 205 generates the reference voltage V_{REF}. After receiving the start signal S_{TR}, the reference voltage generating circuit 205 generates the stop signal S_{TP}. In response to the stop signal S_{TP}, the start-up circuit 250 stops activating the start signal S_{TR}.

In an embodiment, the reference voltage generating circuit 205 includes a bias current generating circuit 210, a proportional to absolute temperature voltage generating circuit (also referred to as a PTAT voltage generating circuit) 220, a complementary to absolute temperature voltage generating circuit (also referred to as a CTAT voltage generating circuit) 230, and a voltage adder 240.

The reference voltage generating circuit 205 generates the reference voltage V_{REF}. The reference voltage V_{REF} is transmitted to the second input terminal of the comparator 270.

The voltage divider 260 receives the input voltage V_{IN} and generates the divided voltage V_{DIV}. The divided voltage V_{DIV} is equal to the proportional value R_{ATIO} multiplied by the input voltage V_{IN} (i.e., V_{DIV}=R_{ATIO}×V_{IN}), where the proportional value R_{ATIO} is a real number greater than zero and less than or equal to 1. Furthermore, the divided voltage V_{DIV} is transmitted to the first input terminal of the comparator 270.

The start-up circuit 250 receives the control signal CTRL from the voltage divider 260, and the start-up circuit 250 operates according to the control signal CTRL. When the start-up circuit 250 is enabled, the start-up circuit 250 activates the start signal S_{TR}. The start signal S_{TR} is transmitted to the bias current generating circuit 210. In response to the start signal S_{TR}, the bias current generating circuit 210 generates bias currents I_{B1} and I_{B2}. When the bias currents I_{B1} and I_{B2} generated by the bias current generating circuit 210 are in the stable state, the bias current generating circuit 210 generates the stop signal S_{TP} to the start-up circuit 250. In response to the stop signal S_{TP}, the start-up circuit 250 stops activating the start signal S_{TR}. Furthermore, when the bias current generating circuit 210 generates the stable bias currents I_{B1} and I_{B2}, the magnitudes of the bias currents I_{B1} and 1_{B2} will hardly change with voltage variation.

The PTAT voltage generating circuit 220 receives the bias current I_{B1} and generates a proportional to absolute temperature voltage (also referred to as a PTAT voltage) V_{PTAT}. The CTAT voltage generating circuit 230 receives the bias current I_{B2} and generates a complementary to absolute temperature voltage (also referred to as a CTAT voltage) V_{CTAT}. The PTAT voltage V_{PTAT} has a positive temperature coefficient. The CTAT voltage V_{CTAT} has a negative temperature coefficient. That is, the PTAT voltage V_{PTAT} gradually increases with the increasing temperature, and the CTAT voltage V_{CTAT} gradually decreases with the increasing temperature.

The voltage adder 240 adds the PTAT voltage V_{PTAT} and the CTAT voltage V_{CTAT} and generates the reference voltage V_{REF}. Furthermore, the reference voltage V_{REF} is transmitted to the second input terminal of the comparator 270. The reference voltage V_{REF} has a zero temperature coefficient. That is, the reference voltage V_{REF} is nearly kept unchanged with the varying temperature.

As mentioned above, the reference voltage V_{REF} generated by the reference voltage generating circuit 205 is nearly kept unchanged with the varying temperature. Consequently, the reference voltage V_{REF} is very stable, and insensitive to the PVT variations, and the comparator 270 can accurately determine the input voltage V_{IN}. When the divided voltage V_{DIV} is lower than the reference voltage V_{REF}, the detection signal O_{DET} generated by the comparator 270 is in the first logic level state (e.g., in the logic high level state). When the divided voltage V_{DIV} is higher than the reference voltage V_{REF}, the detection signal O_{DET} generated by the comparator 270 is in a second logic level state (e.g., a logic low level state).

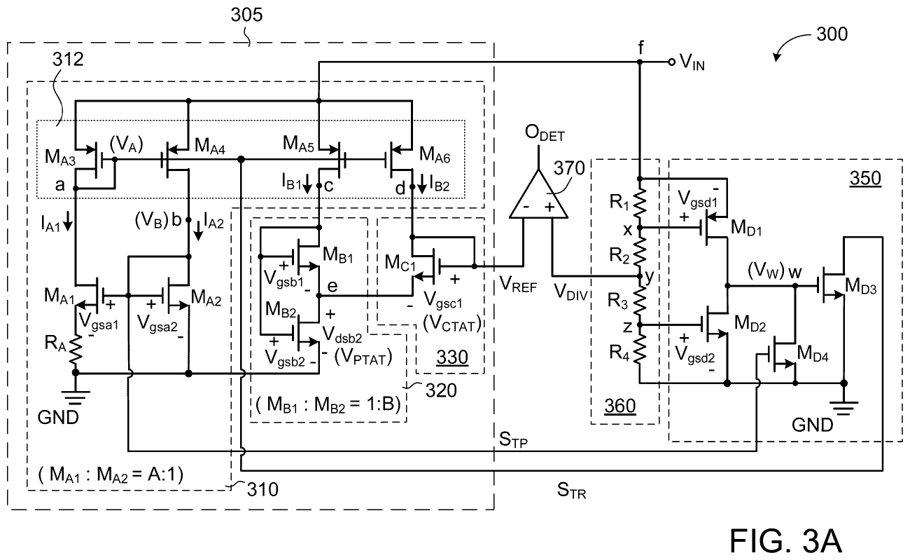

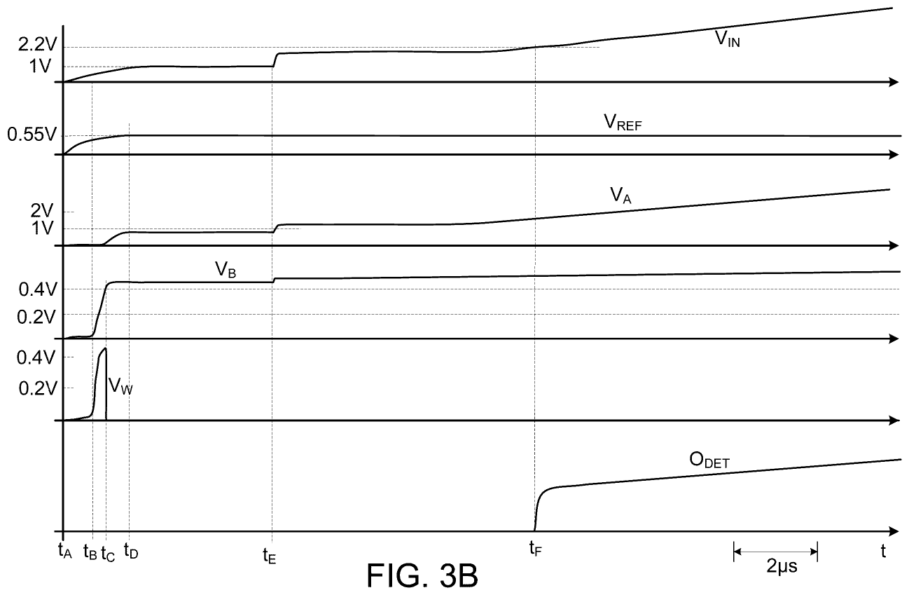

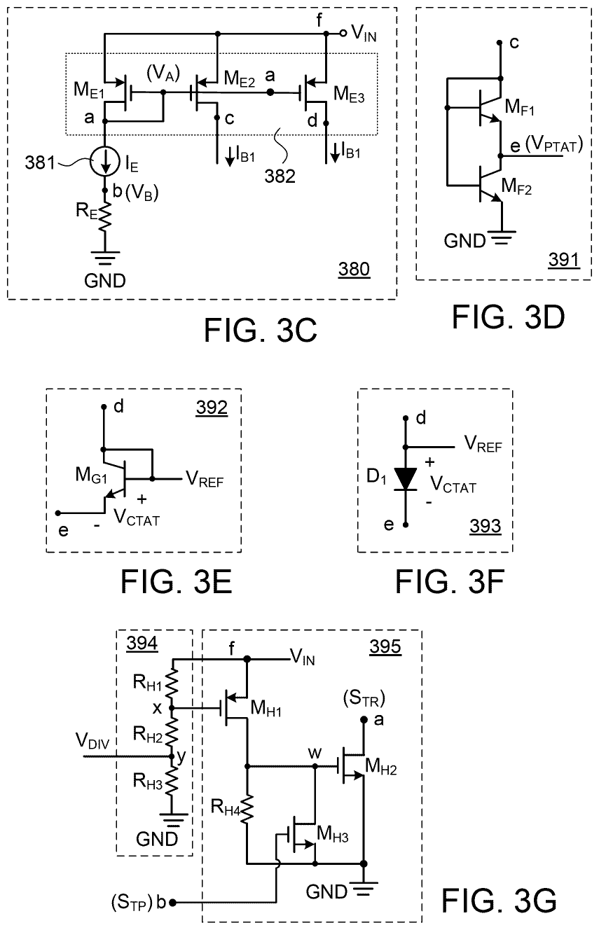

FIG. 3A is a schematic circuit diagram illustrating the detailed circuitry structure of the voltage detector of the present invention. As shown in FIG. 3A, the voltage detector 300 includes a reference voltage generating circuit 305, a comparator 370, a voltage divider 360, and a start-up circuit 350. Furthermore, the reference voltage generating circuit 305 includes a bias current generating circuit 310, a PTAT voltage generating circuit 320, and a CTAT voltage generating circuit 330. The input terminal of the voltage detector 300 receives the input voltage V_{IN}. In addition, the input terminal of the voltage detector 300 is connected to the node f.

The voltage divider 360 includes resistors R₁~R₄. The resistor R₁ is connected between node f and the node x. The resistor R₂ is connected between node x and the node y. The resistor R₃ is connected between node y and the node z. The resistor R₄ is connected between node z and ground terminal GND. Consequently, the divided voltage V_{DIV} is equal to the proportional value R_{ATIO} multiplied by the input voltage V_{IN}, where the proportional value R_{ATIO} is equal to (R₃+R₄)/(R₁+R₂+R₃+R₄). Furthermore, the divided voltage V_{DIV} is transmitted to the first input terminal of the comparator 370. The voltages at the nodes x and z can be used as control signals CTRL to control the start-up circuit 350.

The start-up circuit 350 includes transistors M_{D1}~M_{D4}. The source terminal of the transistor M_{D1} is connected to the node f to receive the input voltage V_{IN}. The gate terminal of the transistor M_{D1} is connected to the node x. The drain terminal of the transistor M_{D1} is connected to the node w. The drain terminal of the transistor M_{D2} is connected to the node w. The gate terminal of the transistor M_{D2} is connected to the node z. The source terminal of the transistor M_{D2} is connected to the ground terminal GND. The drain terminal of the transistor M_{D3} is connected to the node a. The drain voltage of the transistor M_{D3} serves as the start signal S_{TR}. The gate terminal of the transistor M_{D3} is connected to the node w. The source terminal of the transistor M_{D3} is connected to the ground terminal GND. The drain terminal of the transistor M_{D4} is connected to the node w. The gate terminal of the transistor M_{D4} is connected to the node b to receive the stop signal S_{TP}. The source terminal of the transistor M_{D4} is connected to ground terminal GND.

The bias current generating circuit 310 includes a current mirror 312, a resistor R_{A}, and transistors M_{A1} and M_{A2}. The first current terminal of the current mirror 312 is connected to the node a. The second current terminal of the current mirror 312 is connected to the node b. The third current terminal of the current mirror 312 is connected to the node c. The fourth current terminal of the current mirror 312 is connected to the node d. The first current terminal outputs a current I_{A1}. The second current terminal outputs a current I_{A2}. The third current terminal outputs a bias current I_{B1}. The fourth current terminal outputs a bias current I_{B2}. Furthermore, the drain terminal of the transistor M_{A1} is connected to the node a, and the gate terminal of the transistor M_{A1} is connected to the node b. The first terminal of the resistor R_{A} is connected to the source terminal of the transistor M_{A1}. The second terminal of the resistor R_{A} is connected to the ground terminal GND. The drain terminal of the transistor M_{A2} is connected to the node b. The gate terminal of the transistor M_{A2} is connected to the node b. The source terminal of the transistor M_{A2} is connected to the ground terminal GND. The voltage V_{B} at the node b serves as the stop signal S_{TP}.

The current mirror 312 includes transistors M_{A3}~M_{A6}. The source terminal of the transistor M_{A3} is connected to the node f to receive the input voltage V_{IN}. The gate terminal of the transistor M_{A3} is connected to the node a. The drain terminal of the transistor M_{A3} is connected to the node a. The source terminal of the transistor M_{A4} is connected to the node f. The gate terminal of the transistor M_{A4} is connected to the node a. The drain terminal of the transistor M_{A4} is connected to the node b. The source terminal of the transistor M_{A5} is connected to the node f. The gate terminal of the transistor M_{A5} is connected to the node a. The drain terminal of the transistor M_{A5} is connected to the node c. The source terminal of the transistor M_{A6} is connected to the node f. The gate terminal of the transistor M_{A6} is connected to the node a. The drain terminal of the transistor M_{A6} is connected to the node d.

The PTAT voltage generating circuit 320 includes transistors M_{B1} and M_{B2}. The drain terminal of the transistor M_{B1} is connected to the node c. The gate terminal of the transistor M_{B1} is connected to the node c. The source terminal of the transistor M_{B1} is connected to the node e. The drain terminal of the transistor M_{B2} is connected to the node e. The gate terminal of the transistor M_{B2} is connected to the node c. The source terminal of the transistor M_{B2} is connected to ground terminal GND.

The CTAT voltage generating circuit 330 includes a transistor M_{C1}. The drain terminal of the transistor M_{C1} is connected to the node d. The gate terminal of the transistor M_{C1} is connected to the node d. The source terminal of the transistor M_{C1} is connected to the node e. Furthermore, the voltage at the node d serves as a reference voltage V_{REF}. The reference voltage V_{REF} is inputted into the second input terminal of the comparator 370.

The operations of all circuits will be described in detail as follows. Firstly, the bias current generating circuit 310 will be introduced. It is assumed that the transistors M_{A1} and M_{A2} have the same threshold voltage Vₜₕ and operate in the saturation region, and the transistors M_{A3} and M_{A4} operate in the saturation region. Furthermore, the ratio of the aspect ratio of the transistor M_{A1} to the aspect ratio of the transistor M_{A2} is A:1. That is, the value of the aspect ratio of the transistor M_{A1} to the transistor M_{A2} is A, where A is a positive real number. Furthermore, the transistors M_{A3}~M_{A6} in the current mirror 312 have the same aspect ratio. Consequently, the currents I_{A1}, I_{A2}, I_{B1} and I_{B2} have the same magnitude. Of course, the current mirror 312 can be specially designed to provide other proportional relationships between the currents I_{A1}, I_{A2}, I_{B1} and I_{B2}.

The relationships between associated currents and voltages may be expressed as: I_{A1}=A×Kₙ×(V_{gsa1}−Vₜₕ)²=Kₙ×(V_{gsa2}−Vₜₕ)²=I_{A2}, where Kₙ is the device parameter of the transistor M_{A2}, and V_{gsa1} and V_{gsa2} are respectively the gate-source voltage of the transistor M_{A1} and the gate-source voltage of the transistor M_{A2}. Since the currents I_{A1} and I_{A2} have the same magnitude, the following equation can be deduced: \sqrt{A}×(V_{gsa1}−Vₜₕ)=(V_{gsa2}−Vₜₕ).

Furthermore, V_{gsa2}=V_{gsa1}+I_{A1}×R_{A}, and (V_{gsa1}−Vₜₕ)=2×I_{A1}/gₘ₁, where gₘ₁ is the transconductance of the transistor M_{A1}. That is, gₘ₁×R_{A}=2×(\sqrt{A} −1). Obviously, during the normal operation, the bias current generating circuit 310 acts as a constant gₘ circuit, and (gₘ₁×R_{A}) remains at a fixed value 2×(\sqrt{A}−1). In other words, the value (gₘ₁×R_{A}) will not change with voltage.

It is assumed that the transistors M_{B1} and M_{B2} in the PTAT voltage generating circuit 320 operate in a subthreshold region. Furthermore, the ratio of the aspect ratio of the transistor M_{B1} to the aspect ratio of the transistor M_{B2} is 1:B. That is, the ratio of the aspect ratio of the transistor M_{B1} to the transistor M_{B2} is 1/B, where B is a positive real number. The current flowing through the transistor M_{B1} is expressed as:

$${I}_{B 1} = {I}_{0} \times {e}^{\frac{{V}_{gsb 1}}{{V}_{T}}} ,$$

where I₀ is the saturation current of the transistor M_{B1}, V_{T} is the thermal voltage, and V_{gsb1} is the gate-source voltage of the transistor M_{B1}. Similarly, the current flowing through transistor M_{B2} is expressed as:

$$( {I}_{B 1} + {I}_{B 2} ) = 2 \times {I}_{B 1} = B \times {I}_{0} \times {e}^{\frac{{V}_{gsb 2}}{{V}_{T}}} .$$

Consequently, the following equation can be deduced: (V_{gsb2}−V_{gsb1})=V_{T}×In(2/B), where V_{gsb2} is the gate-source voltage of the transistor M_{B2}.

Furthermore, V_{dsb2}=(V_{gsb2}−V_{gsb1})=V_{T}×In(2/B), where In (2/B) is a constant, and V_{dsb2} is the drain-source voltage of the transistor M_{B2}. Obviously, the drain-source voltage V_{dsb2} of the transistor M_{B2} is equal to the constant multiplied by the thermal voltage V_{T}, and the thermal voltage V_{T} increases with the increasing temperature. For example, the positive temperature coefficient of the thermal voltage V_{T} is +0.08 mV/° C. That is, for every 1° C. increase, the thermal voltage V_{T} increases by 0.08 mV. In other words, the drain-source voltage V_{dsb2} of the transistor M_{B2} can be used as the PTAT voltage V_{PTAT}.

In the CTAT voltage generating circuit 330, a current I_{B2} flows through the diode-connected transistor M_{C1}, and thus the gate-source voltage V_{gsc1} of the transistor M_{C1} has a negative temperature coefficient. For example, the negative temperature coefficient of the gate-source voltage V_{gsc1} is −2 mV/° C. That is, for every 1° C. increase, the gate-source voltage V_{gsc1} decreases by 2 mV. In other words, the gate-source voltage V_{gsc1} of the transistor M_{C1} can be used as the CTAT voltage V_{CTAT}.

In FIG. 3A, the source terminal of the transistor M_{C1} is connected to the node e. This connection can be regarded as a voltage adder to generate the reference voltage V_{REF}. In addition, the reference voltage V_{REF} is transmitted to the second input terminal of the comparator 370. Therefore, V_{REF}=V_{dsb2}+V_{gsc1}=V_{T}×In(2/B)+V_{gsc1}=V_{PTAT}+V_{CTAT}. Furthermore, by appropriately designing the constant In (2/B), a reference voltage V_{REF} corresponding to the zero-temperature coefficient can be obtained.

The voltage detector 300 is additionally equipped with the start-up circuit 350. When the voltage detector 300 receives the input voltage V_{IN}, the start-up circuit 350 controls the reference voltage generating circuit 305 to ensure that the reference voltage generating circuit 305 can operate normally to generate the reference voltage V_{REF}. Consequently, the voltage detector 300 can automatically detect the input voltage V_{IN}.

When the voltage detector 300 receives the input voltage V_{IN} and the input voltage V_{IN} gradually rises, the gate-source voltage V_{gsd1} of the transistor M_{D1} is negative and gradually decreases. When the gate-source voltage V_{gsd1} is less than the threshold voltage (Vₜₚ) of the transistor M_{D1}, the transistor M_{D1} is turned on, and the voltage V_{W} at the node w is pulled up to the input voltage V_{IN}. In addition, the transistor M_{D3} is turned on, and the start signal S_{TR} is the ground voltage (0 V). Therefore, in the current mirror 312 of the bias current generating circuit 310, the voltage V_{A} at the node a is the ground voltage (0 V), and the transistors M_{A3}~M_{A6} are fully turned on. In addition, the current mirror 312 generates the maximum currents I_{A1}, I_{A2}, I_{B1} and I_{B2}, causing the voltage V_{B} at the node b to rise.

The voltage V_{B} at node b serves as the stop signal S_{TP}. Consequently, when the voltage V_{B} at the node b rises to the voltage level greater than the threshold voltage (Vₜₙ) of the transistor M_{D4}, the transistor M_{D4} is turned on, and the voltage V_{W} at the node w is pulled down to the ground voltage (0 V). In addition, the transistor M_{D3} is turned off, and the start signal S_{TR} is in a floating state. In the bias current generating circuit 310, the node a is disconnected from the ground terminal GND. Consequently, the currents I_{A1}, I_{A2}, I_{B1} and I_{B2} generated by the current mirror 312 are gradually stabilized.

When the currents I_{A1}, I_{A2}, I_{B1} and I_{B2} are stable, the input voltage V_{IN} is greater than the voltage V_{A}, the voltage V_{A} is greater than the voltage V_{B}, and the voltage V_{B} is greater than the ground voltage (0 V). Furthermore, the PTAT voltage generating circuit 320 and the CTAT voltage generating circuit 330 operate normally, and a stable reference voltage V_{REF} is generated. This reference voltage V_{REF} remains virtually unchanged with the PVT variations in the input voltage V_{IN}.

When the input voltage V_{IN} increases and the divided voltage V_{DIV} exceeds the reference voltage V_{REF}, the comparator 370 changes the logic level state of the detection signal O_{DET}. Meanwhile, the transistor M_{D4} is continuously turned on in response to the stop signal S_{TP}. In addition, the gate-source voltage V_{gsd2} provided by the voltage divider 360 and transmitted to the transistor M_{D2} will also increase. Consequently, the transistor M_{D2} is turned on. In addition, the voltage V_{W} at the node w is ensured to be the ground voltage (0 V), and the transistor M_{D3} is continuously turned off. Since the transistor M_{D3} is continuously turned off, the start signal S_{TR} is maintained in the floating state to prevent malfunction of the bias current generating circuit 310.

FIG. 3B is a schematic timing waveform diagram illustrating associated signals processed by the voltage detector of the present invention. It is assumed that the proportional value R_{ATIO} of the voltage divider 360 is 0.25, the stable reference voltage V_{REF} is 0.55V, and (V_{REF}/R_{ATIO})=2.2V. That is, when the input voltage V_{IN} is lower than 2.2V, the detection signal O_{DET} is in the logic low level state. When the input voltage V_{IN} is higher than 2.2V, the detection signal O_{DET} is in the logic high level state.

Please refer to FIG. 3B again. At the time point ta, the voltage detector 300 receives the input voltage V_{IN}. In addition, the input voltage V_{IN} gradually increases.

At the time point the, the transistor M_{D1} is turned on, and the voltage V_{W} at the node w is pulled up to the input voltage V_{IN}. Furthermore, the transistor M_{D3} is turned on, and the start signal S_{TR} is the ground voltage (0 V). That is, the voltage V_{A} at the node a is pulled down to the ground voltage (0 V). Furthermore, the voltage V_{B} at the node b gradually rises, and the voltage V_{B} is the stop signal S_{TP}.

At the time point t_{C}, the transistor M_{D4} is turned on, and the voltage V_{W} at the node w is pulled down to the ground voltage (0 V). Furthermore, the transistor M_{D3} is turned off, and the node a is disconnected from the ground terminal GND. Consequently, the voltage V_{A} at the node a gradually increases.

At the time point to, the voltage V_{A} at the node a and the voltage V_{B} at the node b reach the stable state, and the reference voltage V_{REF} also reaches the stable state.

In the time interval between the time point ta and the time point the, the detection signal O_{DET} is in the logic low level state.

At the time point the, the input voltage V_{IN} increases, but has not yet exceeded 2.2V. Meanwhile, the voltage V_{A} at the node a and the voltage V_{B} at the node b change slightly. However, the reference voltage V_{REF} is maintained in the stable state, and the detection signal O_{DET} is maintained in the logic low level state.

At the time point tr, the input voltage V_{IN} is abnormal and exceeds 2.2V, and the detection signal O_{DET} changes to the logic high level state.

As mentioned above, when the voltage detector 300 receives the input voltage V_{IN}, the voltage detector 300 automatically activates and detects the magnitude of the input voltage V_{IN}. Of course, as long as the voltage self-detector 300 can still detect the input voltage V_{IN}, the circuitry structure of the voltage self-detector 300 shown in FIG. 3A may be modified.

FIG. 3C is a schematic circuit diagram illustrating a variant example of the bias current generating circuit. As shown in FIG. 3C, the bias current generating circuit 380 includes a current mirror 382, a resistor RE, and a current source 381. The first current terminal of the current mirror 382 is connected to the node a. The second current terminal of the current mirror 382 is connected to the node c. The third current terminal of the current mirror 382 is connected to the node d. The current source 381 is connected between the node a and the node b. The current source 381 generates a constant current IE. Furthermore, the resistor RE is connected between the node b and the ground terminal GND.

Furthermore, the current mirror 382 includes transistors M_{E1}~M_{E3}. The source terminal of the transistor M_{E1} is connected to the node f to receive the input voltage V_{IN}. The gate terminal of the transistor M_{E1} is connected to the node a. The drain terminal of the transistor M_{E1} is connected to the node a to receive the current IE. The source terminal of the transistor M_{E2} is connected to the node f. The gate terminal of the transistor M_{E2} is connected to the node a. The drain terminal of the transistor M_{E2} is connected to the node c to output the bias current I_{B1}. The source terminal of the transistor M_{E3} is connected to the node f. The gate terminal of the transistor M_{E3} is connected to the node a. The drain terminal of the transistor M_{E3} is connected to the node d to output the bias current I_{B2}. Similarly, the voltage V_{B} at the node b serves as the stop signal S_{TP}. The voltage V_{A} at the node a is controlled according to the start signal S_{TR}. Generally, the operations of the bias current generating circuit 380 are similar to those of the bias current generating circuit 310 in FIG. 3A.

FIG. 3D is a schematic circuit diagram illustrating a variant example of the PTAT voltage generating circuit. As shown in FIG. 3D, the PTAT voltage generating circuit 391 includes transistors M_{F1} and M_{F2}. The collector of the transistor M_{F1} is connected to the node c. The base of the transistor M_{F1} is connected to the node c. The emitter of the transistor M_{F1} is connected to the node e. The collector of the transistor M_{F2} is connected to the node e. The base of the transistor M_{F2} is connected to the node c. The emitter of the transistor M_{F2} is connected to the ground terminal GND. Similarly, the voltage at the node e can be used as the PTAT voltage V_{PTAT}.

FIG. 3E is a schematic circuit diagram illustrating a variant example of the CTAT voltage generating circuit. As shown in FIG. 3E, the CTAT voltage generating circuit 392 includes a transistor M_{G1}. The collector of the transistor M_{G1} is connected to the node d. The base of the transistor M_{G1} is connected to the node d. The emitter of the transistor M_{G1} is connected to the node e. Since transistor M_{G1} is a diode-connected transistor, the base-emitter voltage of the transistor M_{G1} is the CTAT voltage V_{CTAT}.

FIG. 3F is a schematic circuit diagram illustrating another variant example of the CTAT voltage generating circuit. As shown in FIG. 3F, the CTAT voltage generating circuit 393 includes a diode D₁. The anode of the diode D₁ is connected to the node d. The cathode of diode D₁ is connected to the node e. Consequently, the voltage difference between the anode and the cathode of the diode is the CTAT voltage V_{CTAT}.

FIG. 3G is a schematic circuit diagram illustrating a variant example of the voltage divider and the start-up circuit. The voltage divider 394 includes resistors R_{H1}~R_{H3}. The resistor R_{H1} is connected between the node f and the node x. The resistor R_{H2} is connected between the node x and the node y. The resistor R_{H3} is connected between the node y and the ground terminal GND. The divided voltage V_{DIV} is equal to the proportional value R_{ATIO} multiplied by the input voltage V_{IN} (i.e., V_{DIV}=R_{ATIO}× V_{IN}). The proportional value R_{ATIO} is equal to (R_{H3})/(R_{H1}+R_{H2}+R_{H3}). Furthermore, the voltage at the node x can be used as the control signal CTRL to control the start-up circuit 395.

The start-up circuit 395 includes transistors M_{H1}~M_{H3} and a resistor R_{H4}. The source terminal of the transistor M_{H1} is connected to the node f to receive the input voltage V_{IN}. The gate terminal of the transistor M_{H1} is connected to the node x. The drain terminal of the transistor M_{H1} is connected to the node w. The resistor R_{H4} is connected between the node w and the ground terminal GND. The drain terminal of the transistor M_{H2} is connected to the node a. The drain voltage of the transistor M_{H2} serves as the start signal S_{TR}. The gate terminal of the transistor M_{H2} is connected to the node w. The source terminal of the transistor M_{H2} is connected to the ground terminal GND. The drain terminal of the transistor M_{H3} is connected to the node w. The gate terminal of the transistor M_{H3} receives the stop signal S_{TP}. The source terminal of the transistor M_{H3} is connected to the ground terminal GND. The operations of the voltage divider 394 and the start-up circuit 395 are similar to those of the voltage divider 360 and the start-up circuit 350 shown in FIG. 3A.

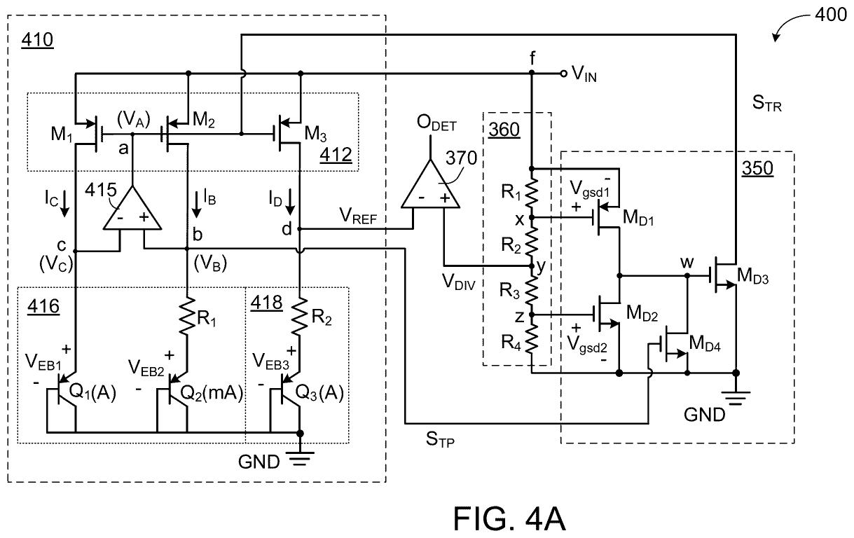

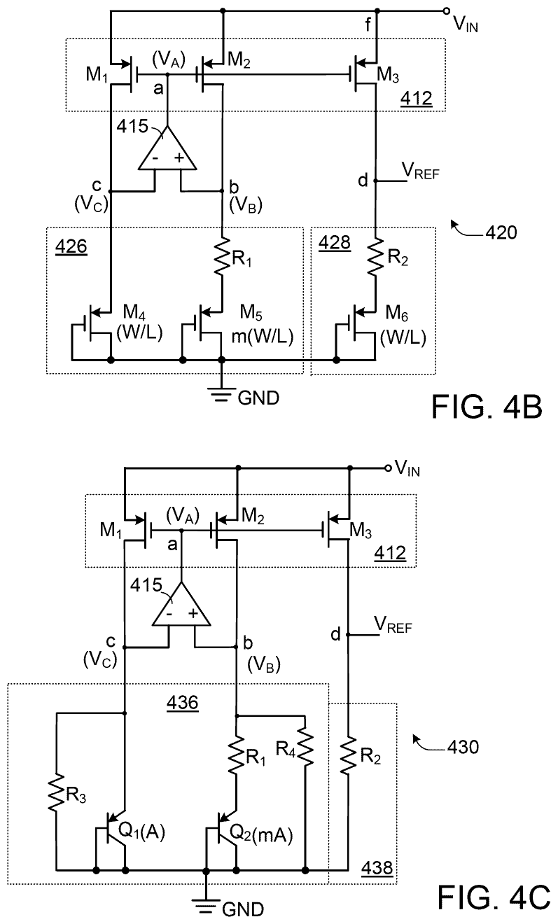

FIG. 4A is a schematic circuit block diagram illustrating the architecture of a voltage detector according to a second embodiment of the present invention. As shown in FIG. 4A, the voltage detector 400 includes a reference voltage generating circuit 410, a comparator 370, a voltage divider 360, and a start-up circuit 350. The voltage divider 360 and the start-up circuit 350 are similar to those of the first embodiment. Alternatively, the voltage divider 360 and the start-up circuit 350 are respectively replaced by the voltage divider 394 and the start-up circuit 395 of FIG. 3G.

The reference voltage generating circuit 410 includes a current mirror 412, an operation amplifier 415, an input circuit 416, and a load circuit 418.

The first current terminal of current mirror 412 is connected to the node c. The second current terminal of current mirror 412 is connected to the node b. The third current terminal of current mirror 412 is connected to the node d. The first current terminal outputs a current I_{C}. The second current terminal outputs a current I_{B}. The third current terminal outputs a current I_{D}. The current mirror 412 includes transistors M₁~M₃. The source terminal of the transistor M₁ is connected to the node f to receive the input voltage V_{IN}. The gate terminal of the transistor M₁ is connected to the node a. The drain terminal of the transistor M₁ is connected to the node c. The source terminal of the transistor M₂ is connected to the node f. The gate terminal of the transistor M₂ is connected to the node a. The drain terminal of the transistor M₂ is connected to the node b. The source terminal of the transistor M₃ is connected to the node f. The gate terminal of the transistor M₃ is connected to the node a. The drain terminal of the transistor M₃ is connected to the node d.

The output terminal of the operation amplifier 415 is connected to the node a in current mirror 412. The inverting input terminal of the operation amplifier 415 is connected to the node c. The non-inverting input terminal of operation amplifier 415 is connected to the node b.

The input circuit 416 is connected to the nodes c and b. The input circuit 416 includes transistors Q₁ and Q₂ and a resistor R₁. The emitter of the transistor Q₁ is connected to the node c. The base and the collector of the transistor Q₁ are connected to the ground terminal GND. Consequently, the transistor Q₁ operates in the diode-connected configuration. The resistor R₁ is connected between the emitter of the transistor Q₂ and the node b. The base and the collector of the transistor Q₂ are connected to the ground terminal GND. Consequently, the transistor Q₂ operates in the diode-connected configuration.

The load circuit 418 is connected to the node d. The load circuit 418 includes a transistor Q₃ and a resistor R₂. The resistor R₂ is connected between the emitter of the transistor Q₃ and the node d. The base and the collector of the transistor Q₃ are connected to ground terminal GND. Consequently, the transistor Q₃ operates in the diode-connected configuration. Furthermore, the node d is the output terminal of reference voltage generating circuit 410, and the voltage at the node d is the reference voltage V_{REF}.

For example, in the current mirror 412, the transistors M₁~M₃ have the same aspect ratio. The area of the transistor Q₂ is m times the area of the transistor Q₁, where m is a positive real number. The area of the transistor Q₃ and the area of the transistor Q₁ are equal. Of course, the aspect ratios of the three transistors M₁~M₃ can be varied according to the practical requirements. Similarly, the area relationships of the three transistors Q₁~Q₃ can also be varied according to the practical requirements.

Since the transistors M₁~M₃ have the same aspect ratio, the currents I_{C}, I_{B} and I_{D} have the same magnitude. That is, I_{D}=I_{B}=I_{C}.

Furthermore, in case that operation amplifier 415 has an infinitely large open-loop gain, the voltage (VC) at the inverting input terminal of the operation amplifier 415 will be equal to the voltage (V_{B}) at the non-inverting input terminal of the operation amplifier 415. Therefore, R₁×I_{B}+V_{EB2}=V_{EB1}, where V_{EB1} is the emitter-base voltage of the transistor Q₁, and V_{EB2} is the emitter-base voltage of the transistor Q₂.

Since the transistors Q₁ and Q₂ are diode-connected and the area of the transistor Q₂ is m times the area of the transistor Q₁,

$${I}_{C} = {I}_{0} \times {e}^{\frac{{V}_{EB 1}}{{V}_{T}}} and {I}_{B} = m \times {I}_{0} \times {e}^{\frac{{V}_{EB 2}}{{V}_{T}}} .$$

In addition, the following expressions can be deduced: V_{EB1}=V_{T}×In(I_{C}/I₀) and V_{EB2}=V_{T}×In[I_{B}/(m×I₀)], where I₀ is the saturation current of the transistor Q₁, and V_{T} is the thermal voltage.

Furthermore, according to the above equations, the reference voltage can be expressed as: V_{REF}=(R₂/R₁)×In(m)×V_{T}+V_{EB3}, where V_{EB3} is the emitter-base voltage of the transistor Q₃. Obviously, the reference voltage V_{REF} can be regarded as the base-emitter voltage V_{BE3} plus the product of the thermal voltage V_{T} and a temperature-independent constant [(R₂/R₁)×In(m)].

Generally, the base-emitter voltage V_{BE3} has a negative temperature coefficient, and the thermal voltage V_{T} has a positive temperature coefficient. Consequently, the reference voltage V_{REF} with the zero temperature coefficient can be obtained through the proper adjustment of the constant [(R₂/R₁)×In(m)]. In other words, the reference voltage V_{REF} is almost a constant value at any temperature, and thus the reference voltage V_{REF} hardly changes with temperature. Furthermore, the reference voltage V_{REF} can also be referred to as a bandgap reference voltage.

As mentioned above, when the reference voltage generating circuit 410 operates normally, the reference voltage generating circuit 410 generates the bandgap voltage V_{BG} that does not change with temperature. Furthermore, the start-up circuit 395 of the second embodiment can control the reference voltage generating circuit 410 to ensure that the reference voltage generating circuit 410 can operate normally to generate the reference voltage V_{REF}.

When the voltage detector 400 receives the input voltage V_{IN} and the input voltage V_{IN} gradually rises, the gate-source voltage V_{gsd1} of the transistor M_{D1} is negative and gradually decreases. When the gate-source voltage V_{gsd1} is lower than the threshold voltage (Vₜₚ) of the transistor M_{D1}, the transistor M_{D1} is turned on, and the voltage V_{W} at the node w is pulled up to the input voltage V_{IN}. In addition, the transistor M_{D3} is turned on, and the start signal S_{TR} is the ground voltage (0 V). Therefore, in the current mirror 412 of the bias current generating circuit 410, the voltage V_{A} at the node a is the ground voltage (0 V), the transistors M₁~M₃ are fully turned on. In addition, the current mirror 412 generates the maximum currents I_{C}, I_{B} and I_{D}, causing the voltage V_{B} at the node b to rise.

The voltage V_{B} at node b serves as the stop signal S_{TP}. Consequently, when the voltage V_{B} at the node b rises to the voltage level greater than the threshold voltage (Vₜₙ) of the transistor M_{D4}, the transistor M_{D4} is turned on, and the voltage V_{W} at the node w is pulled down to the ground voltage (0 V). In addition, the transistor M_{D3} is turned off, and the start signal S_{TR} is in a floating state. In the bias current generating circuit 410, the node a is disconnected from the ground terminal GND. Consequently, the currents I_{C}, I_{B} and I_{D} generated by the current mirror 412 are gradually stabilized, and the stable reference voltage V_{REF} is generated.

When the input voltage V_{IN} increases and the divided voltage V_{DIV} exceeds the reference voltage V_{REF}, the comparator 370 changes the logic level state of the detection signal O_{DET}. Meanwhile, the transistor M_{D4} is continuously turned on in response to the stop signal S_{TP}. In addition, the gate-source voltage V_{gsd2} provided by the voltage divider 360 and transmitted to the transistor M_{D2} will also increase. Consequently, the transistor M_{D2} is turned on. In addition, the voltage V_{W} at the node w is ensured to be the ground voltage (0 V), and the transistor M_{D3} is continuously turned off. Since the transistor M_{D3} is continuously turned off, the start signal S_{TR} is maintained in the floating state to prevent malfunction of the bias current generating circuit 410.

Of course, as long as the voltage detector 400 can still detect the input voltage V_{IN}, the circuitry structure of the reference voltage generating circuit 410 in the voltage detector 400 shown in FIG. 4A may be modified.

FIG. 4B is a schematic circuit diagram illustrating a variant example of the reference voltage generating circuit in the voltage detector according to the second embodiment of the present invention. As shown in FIG. 4B, the reference voltage generating circuit 420 includes a current mirror 412, an operation amplifier 415, an input circuit 426, and a load circuit 428. For brevity, only the input circuit 426 and the load circuit 428 will be described as follows.

The input circuit 426 is connected to the node c and the node b. The input circuit 426 includes transistors M₄ and M₅. The aspect ratio of the transistor M₅ is m times the aspect ratio of the transistor M₄. The gate terminal and the drain terminal of the transistor M₄ are connected to the ground terminal GND. Consequently, the transistor M₄ operates in the diode-connected configuration. The gate terminal and the drain terminal of the transistor M₅ are connected to the ground terminal GND. Consequently, the transistor M₅ operates in the diode-connected configuration. In addition, the source terminal of the transistor M₄ is connected to the node c, and a resistor R₁ is connected between the source terminal of the transistor M₅ and the node b.

The load circuit 428 is connected to the node d. The load circuit 428 includes a transistor M₆. A resistor R₂ is connected between the source terminal of the transistor M₆ and the node d. The gate terminal and the drain terminal of the transistor M₆ are connected to the ground terminal GND. Consequently, the transistor M₆ operates in the diode-connected configuration. In addition, the voltage at the node d is the reference voltage V_{REF}.

FIG. 4C is a schematic circuit diagram illustrating another variant example of the reference voltage generating circuit in the voltage detector according to the second embodiment of the present invention. As shown in FIG. 4C, the reference voltage generating circuit 430 includes a current mirror 412, an operation amplifier 415, an input circuit 436, and a load circuit 438. For brevity, only the input circuit 436 and the load circuit 438 will be described as follows.

The Input circuit 436 is connected to the node c and the node b. The input circuit 436 includes transistors Q₁ and Q₂ and resistors R₁~R₃. The emitter of the transistor Q₁ is connected to the node c. The base and collector of the transistor Q₁ are connected to the ground terminal GND. The resistor R₃ is connected between node c and the ground terminal GND. The resistor R₁ is connected between the emitter of the transistor Q₂ and the node b. The base and the collector of the transistor Q₂ are connected to the ground terminal GND. The resistor R₄ is connected between the node b and the ground terminal GND.

The load circuit 438 is connected to the node d. The load circuit 438 includes the resistor R₂. The resistor R₂ is connected between the node d and the ground terminal GND. The voltage at the node d is the reference voltage V_{REF}.

It is noted that the reference voltage generating circuit in FIG. 4C can be further modified. For example, the transistors Q₁ and Q₂ in the input circuit 436 of FIG. 4C can be replaced by the transistors M₄ and M₅ in FIG. 4B.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A voltage detector receiving an input voltage, the voltage detector comprising:
a comparator having a first input terminal and a second input terminal, wherein an output terminal of the comparator generates a detection signal;
a voltage divider receiving the input voltage, and generating a divided voltage and a control signal according to the input voltage, wherein the divided voltage is transmitted to the first input terminal of the comparator, and the divided voltage is equal to a proportional value multiplied by the input voltage, where the proportional value is a real number greater than zero and less than or equal to 1;
a reference voltage generating circuit receiving the input voltage and a start signal, and generating a reference voltage and a stop signal, wherein the reference voltage is transmitted to the second input terminal of the comparator; and
a start-up circuit receiving the input voltage, the control signal and the stop signal, wherein the start-up circuit is enabled according to the control signal,
wherein when the start-up circuit is enabled, the start signal is activated by the start-up circuit, so that the reference voltage generating circuit generates the reference voltage,
wherein after the reference voltage generating circuit reaches a stable state in response to the start signal, the reference voltage generating circuit generates the stop signal, and the start-up circuit stops activating the start signal.

2. The voltage detector as claimed in claim 1, wherein the reference voltage generating circuit comprises:
a bias current generating circuit receiving the input voltage and the start signal, and generating the stop signal, wherein after the start signal is activated, the bias current generating circuit generates a first bias current and a second bias current, when the first bias current and the second bias current are in the stable state, the reference voltage generating circuit generates the stop signal;
a proportional to absolute temperature (PTAT) voltage generating circuit receiving the first bias current, and generating a PTAT voltage;
a complementary to absolute temperature (CTAT) voltage generating circuit receiving the second bias current, and generating a CTAT voltage; and
a voltage adder receiving the PTAT voltage and the CTAT voltage, wherein the voltage adder adds the PTAT voltage and the CTAT voltage and generates the reference voltage.

3. The voltage detector as claimed in claim 2, wherein the bias current generating circuit comprises:
a current mirror having a first current terminal, a second current terminal, a third current terminal and a fourth current terminal, wherein the first current terminal is connected to a first node, the second current terminal is connected to a second node, the third current terminal is connected to a third node, and the fourth current terminal is connected to a fourth node;
a first transistor, wherein a drain terminal of the first transistor is connected to the first node, and a gate terminal of the first transistor is connected to the second node;
a first resistor, wherein a first terminal of the first resistor is connected to a source terminal of the first transistor, and a second terminal of the first resistor is connected to a ground terminal; and
a second transistor, wherein a drain terminal of the second transistor is connected to the second node, a gate terminal of the second transistor is connected to the second node, and a source terminal of the second transistor is connected to the ground terminal,
wherein the first transistor has a first aspect ratio, the second transistor has a second aspect ratio, and a ratio of the first aspect ratio to the second aspect ratio is a positive real number,
wherein the first node is connected to the start-up circuit to receive the start signal, and a voltage at the second node serves as the stop signal.

4. The voltage detector as claimed in claim 3, wherein the current mirror comprises:
a third transistor, wherein a source terminal of the third transistor receives the input voltage, a gate terminal of the third transistor is connected to the first node, and a drain terminal of the third transistor is connected to the first node;
a fourth transistor, wherein a source terminal of the fourth transistor receives the input voltage, a gate terminal of the fourth transistor is connected to the first node, and a drain terminal of the fourth transistor is connected to the second node;
a fifth transistor, wherein a source terminal of the fifth transistor receives the input voltage, a gate terminal of the fifth transistor is connected to the first node, and a drain terminal of the fifth transistor is connected to the third node; and
a sixth transistor, wherein a source terminal of the sixth transistor receives the input voltage, a gate terminal of the sixth transistor is connected to the first node, and a drain terminal of the sixth transistor is connected to the fourth node,
wherein the first bias current flows through the third node, and the second bias current flows through the fourth node.

5. The voltage detector as claimed in claim 2, wherein the PTAT voltage generating circuit comprises:
a first transistor, wherein a drain terminal of the first transistor is connected to the third node, a gate terminal of the first transistor is connected to the third node, and a source terminal of the first transistor is connected to a fifth node; and
a second transistor, wherein a drain terminal of the second transistor is connected to the fifth node, a gate terminal of the second transistor is connected to the third node, and a source terminal of the second transistor is connected to the ground terminal,
wherein the first transistor has a first aspect ratio, the second transistor has a second aspect ratio, and a ratio of the first aspect ratio to the second aspect ratio is a positive real number, wherein a drain-source voltage of the second transistor is the PTAT voltage.

6. The voltage detector as claimed in claim 2, wherein the CTAT voltage generating circuit comprises a third transistor, wherein a drain terminal of the third transistor is connected to the fourth node, a gate terminal of the third transistor is connected to the fourth node, a source terminal of the third transistor is connected to the fifth node, a gate-source voltage of the third transistor is the CTAT voltage, and a voltage at the fourth node is the reference voltage.

7. The voltage detector as claimed in claim 1, wherein the control signal includes a first control signal and a second control signal and the voltage divider comprises:
a first resistor, wherein a first terminal of the first resistor receives the input voltage, and a second terminal of the first resistor is connected to a first node that provides the first control signal;
a second resistor, wherein a first terminal of the second resistor is connected to the first node, and a second terminal of the second resistor is connected to a second node, wherein a voltage at the second node is the divided voltage;
a third resistor, wherein a first terminal of the third resistor is connected to the second node, and a second terminal of the third resistor is connected to a third node that provides the second control signal; and
a fourth resistor, wherein a first terminal of the fourth resistor is connected to the third node, and a second terminal of the fourth resistor is connected to a ground terminal.

8. The voltage detector as claimed in claim 7, wherein the start-up circuit comprises:
a first transistor, wherein a source terminal of the first transistor receives the input voltage, a gate terminal of the first transistor is connected to the first node to receive the first control signal, and a drain terminal of the first transistor is connected to a fourth node;
a second transistor, wherein a drain terminal of the second transistor is connected to the fourth node, a gate terminal of the second transistor is connected to the third node to receive the second control signal, and a source terminal of the second transistor is connected to the ground terminal;
a third transistor, wherein a drain voltage of the third transistor serves as the start signal, a gate terminal of the third transistor is connected to the fourth node, and a source terminal of the third transistor is connected to the ground terminal; and
a fourth transistor, wherein a drain terminal of the fourth transistor is connected to the fourth node, a gate terminal of the fourth transistor receives the stop signal, and a source terminal of the fourth transistor is connected to the ground terminal.

9. The voltage detector as claimed in claim 8, wherein when the input voltage gradually rises, a gate-source voltage of the first transistor is negative and gradually decreases; when the gate-source voltage of the first transistor is lower than a threshold voltage of the first transistor, the first transistor is turned on and a voltage at the fourth node is pulled up to the input voltage for turning on the third transistor; and, when the third transistor is turned on, the start signal is activated.

10. The voltage detector as claimed in claim 9, wherein when the stop signal generated by the reference voltage generating circuit rises to a voltage level greater than a threshold voltage of the fourth transistor, the fourth transistor is turned on and the third transistor is turned off; and, when the third transistor is turned off, the start-up circuit stops activating the start signal.

11. The voltage detector as claimed in claim 1, wherein the reference voltage generating circuit comprises:
a current mirror having a first current terminal, a second current terminal and a third current terminal, wherein the current mirror receives the input voltage, a first node in the current mirror receives the start signal, the second current terminal is connected to a second node, the first current terminal is connected to a third node, and the third current terminal is connected to a fourth node;
an operation amplifier, wherein a first input terminal of the operation amplifier is connected to the third node, a second input terminal of the operation amplifier is connected to the second node, and an output terminal of the operation amplifier is connected to the first node;
an input circuit connected to the second node and the third node; and
a load circuit connected to the fourth node,
wherein a voltage at the second node serves as the stop signal, and a voltage at the fourth node serves as the reference voltage.

12. The voltage detector as claimed in claim 11, wherein the current mirror comprises:
a first transistor, wherein a source terminal of the first transistor receives the input voltage, a gate terminal of the first transistor is connected to the first node, and a drain terminal of the first transistor is connected to the third node;
a second transistor, wherein a source terminal of the second transistor receives the input voltage, a gate terminal of the second transistor is connected to the first node, and a drain terminal of the second transistor is connected to the second node; and
a third transistor, wherein a source terminal of the third transistor receives the input voltage, a gate terminal of the third transistor is connected to the first node, and a drain terminal of the third transistor is connected to the fourth node.

13. The voltage detector as claimed in claim 11, wherein the input circuit comprises:
a first transistor, wherein an emitter of the first transistor is connected to the third node, a base of the first transistor is connected to a ground terminal, and a collector of the first transistor is connected to the ground terminal;
a first resistor, wherein a first terminal of the first resistor is connected to the second node; and
a second transistor, wherein an emitter of the second transistor is connected to a second terminal of the first resistor, a base of the second transistor is connected to the ground terminal, and a collector of the second transistor is connected to the ground terminal,
wherein an area of the second transistor is m times an area of the first transistor, where m is a positive real number.

14. The voltage detector as claimed in claim 13, wherein the load circuit comprises:
a second resistor, wherein a first terminal of the second resistor is connected to the fourth node;
a third transistor, wherein an emitter of the third transistor is connected to a second terminal of the second resistor, a base of the third transistor is connected to the ground terminal, and a collector of the third transistor is connected to the ground terminal; and
wherein an area of the third transistor is equal to the area of the first transistor.
